(19) United States
(12) Patent Application Publication
(10) Pub. No.: US 2005/0121225 A1
(43) Pub. Date: Jun. 9, 2005

(54) Multi-layer circuit board and method for fabricating the same

(75) Inventor: Shih-Ping Hsu, Hsin-chu (TW)

Correspondence Address: Mr. William F. Nixon;SQUIRE SANDERS & DEMPSEY LLP, 8000 Towers Crescent Drive, 14th Floor, Tysons Corner, VA, 22182-2700, US

(73) Assignee: Phoenix Precision Technology Corporation

(21) Appl. No.: 10/876,476

(22) Filed: Jun. 28, 2004

(30) Foreign Application Priority Data
Dec. 3, 2003 (TW) 092133971
Dec. 3, 2003 (TW) 092133973

(51) Int. Cl. H05K 1/03

(52) U.S. Cl. 174/255; 174/258; 29/830

(57) ABSTRACT

A multi-layer circuit board and a method for fabricating the same are proposed. A plurality of circuit board units are prepared and formed with patterned circuit layers thereon. At least one insulating layer is formed on each of the circuit board units. The insulating layer is patterned to form a plurality of opening or is thinned to expose contact pads of the circuit layers on the circuit board units. The circuit board units undergo surface activation and laminating processes in vacuum to form a multi-layer circuit board, wherein the circuit board units are laminated and electrically connected together by the exposed contact pads. This method reduces the time and cost for fabrication.

### FIELD OF THE INVENTION

The present invention relates to multi-layer circuit boards and methods for fabricating the same, and more particularly, to a multi-layer circuit board for carrying and packaging a semiconductor chip, and a fabrication method of the multi-layer circuit board.

### BACKGROUND OF THE INVENTION

Along with the blooming development of electronic industry, electronic products are gradually becoming more multi-functional and high efficient. In order to satisfy the requirements of high integration and miniaturization for semiconductor packages, a circuit board for carrying active/passive components and circuits is developed from a double-layer structure into a multi-layer circuit board, which is accomplished using the interlayer connection technique to enlarge usable area of the circuit board with limited space, so as to incorporate integrated circuits of high wiring density in the circuit board.

The multi-layer circuit board is conventionally fabricated by the laminating press process or build-up process.

The laminating press process involves preparing a plurality of substrates made of copper foils and insulating materials, each of the substrates having conductive vias and circuit layers on top and bottom surfaces thereof. Then, prepreg made of fiber or thermosetting resin such as epoxy resin, phenolic polyester and so on is used as an adhesive layer and disposed between any two of the substrates, such that laminating and heat press procedures are performed to form the stack of substrates as a multi-layer board. Afterwards, the multi-layer board is drilled to form a plurality of via holes, and the inner walls of the via holes are plated with a conductive metal layer so as to allow the stacked substrates to be electrical interconnected by these via holes. This completes fabrication of the multi-layer circuit board.

FIGS. 1A to 1F show another method to fabricate a multi-layer circuit board using the laminating press process. As shown in FIG. 1A, the first step is to prepare a plurality of thermoplastic insulating substrate 12 each having a copper foil 11 thereon (only one substrate 12 is shown in FIG. 1A). As shown in FIG. 1B, the next step is to pattern the copper foil 11 to form a patterned circuit layer 13. Then, as shown in FIG. 1C, a plurality of via holes 14 are formed from a side of the substrate 12 not having the circuit layer 13, to expose the part of the circuit layer 13 predetermined for electrical connection. As shown in FIG. 1D, a conductive material such as tin or silver paste 15 is applied and filled in the via holes 14. As shown in FIGS. 1E and 1F, the plurality of substrates 12 having the via holes 14 filled with tin or silver paste 15 are pressed together in a high temperature condition, wherein the tin or silver paste 15 melts under the high temperature to form the electrical connection between the circuit layers 13 of the neighboring substrates 12, such that the multi-layer circuit board is fabricated.

However, the above laminating press process for fabricating the multi-layer circuit board has significant drawbacks. The multi-layer circuit board is formed with conductive via holes, which reduces the flexibility of circuit routability on the circuit board. Alternatively, the electrical interconnection for the insulating substrates constituting the multi-layer circuit board is accomplished by filling the conductive material such as tin or silver paste in the via holes of the substrates; this method however requires extra cost on the conductive material and also makes the fabrication procedures more complex. Furthermore, the laminating press process is carried out in the high temperature environment, the fabricated circuit board may be subject to warpage due to thermal stress generated by mismatch of CTE (coefficient of thermal expansion) between circuit layers and insulating layers, which adversely affects the production yield.

Accordingly, FIGS. 2A to 2E show the build-up method to fabricate a multi-layer circuit board. As shown in FIG. 2A, first, a core substrate 21 is prepared comprising a resin layer 211 having a predetermined thickness, a circuit layer 212 respectively formed on top and bottom surfaces of the resin layer 211, and a plurality of conductive vias 213 formed through the resin layer 211 for electrically interconnecting the circuit layers 212 on the top and bottom surfaces of the resin layer 211. As shown in FIG. 2B, a build-up procedure is performed to apply an insulating layer 22 respectively on the top and bottom surfaces of the core substrate 21, wherein each insulating layer 22 has a plurality of blind holes 23 exposing the corresponding circuit layer 212. As shown in FIG. 2C, a metallic conductive film 24 is coated over the respective insulating layer 22 by the electroless plating or sputtering technique, and then a patterned resist layer 25 having a plurality of openings 250 is disposed on the metallic conductive film 24, wherein the openings 250 expose the part of the conductive film 24 predetermined for subsequent patterned circuitry. As shown in FIG. 2D, a patterned circuit layer 26 and conductive vias 23a are formed by plating a conductive material in the openings 250 of the resist layer 25, such that the circuit layer 26 can be electrically connected to the circuit layer 212 by the conductive vias 23a. Then, the resist layer 25 and the part of the conductive film 24 below the resist layer 25 are stripped. This thus forms a first build-up structure 20a. Similarly, as shown in FIG. 2E, more build-up layers (such as second build-up structure 20b) can be formed by the above method repeatedly on the first build-up structure 20a so as to fabricate a multi-layer circuit board 20.

However, by the above fabrication method, the build-up circuit layers need to be formed one by one and from inside to outside; if one of the circuit layers fails during fabrication, the entire multi-layer circuit board must be discarded, thereby wasting the cost and affecting the production yield. Besides, the build-up method is complex to implement and requires high equipment cost and long cycle time unsuitable for mass production.

Therefore, the problem to be solved here is to provide a multi-layer circuit board and a fabrication method thereof, by which the fabrication processes are simplified, the cost can be reduced and the production yield can be improved.

### SUMMARY OF THE INVENTION

An objective of the present invention is to provide a multi-layer circuit board and a method for fabricating the same, by which circuits can be simultaneously formed on a plurality of circuit board units that are then connected together to form the multi-layer circuit board.

Another objective of the invention is to provide a multi-layer circuit board and a method for fabricating the same, which can simplify the fabrication processes, reduce the cost and improve the production yield.

A further objective of the invention is to provide a multi-layer circuit board and a method for fabricating the same, by which the circuit board is fabricated under the room temperature so as to avoid the occurrence of inappropriate thermal stress and warpage.

In order to achieve the above and other objectives, the present invention proposes a method for fabricating a multi-layer circuit board including: providing a plurality of circuit board units each with patterned circuit layers; forming at least one insulating layer on each of the circuit board units to cover at least one of the circuit layers, and forming a plurality of openings through the insulating layer to expose contact pads of the circuit layer; and placing the circuit board units in vacuum to perform surface activation and laminating processes to form the multi-layer circuit board, wherein the circuit board units are electrically interconnected by the contact pads.

In another preferred embodiment, the method for fabricating a multi-layer circuit board according to the include: providing a plurality of circuit board units each with patterned circuit layers; forming at least one insulating layer on each of the circuit board units to cover at least one of the circuit layers, and thinning the insulating layer to expose contact pads of the circuit layer; and placing the circuit board units in vacuum to perform surface activation and laminating processes to form the multi-layer circuit board, wherein the circuit board units are electrically interconnected by the contact pads.

The surfaces of the circuit board units are flattened and cleaned to remove any oxidation layer and contamination so as to ensure the quality of the surfaces ready for the surface activation process. Moreover, the circuit board units after lamination can be baked to dissipate any remaining moisture and increase the bonding strength.

The multi-layer circuit fabricated according to the above method includes a plurality of laminated circuit board units with an insulating layer disposed between the adjacent circuit board units, the insulating layer is thinned to expose contact pads of circuit layers formed on the circuit board units, so as to allow the circuit board units to be laminated and electrically connected together by the exposed contact pads, the circuit board units having their laminated surfaces activated.

According to another preferred embodiment, the fabricated multi-layer circuit board includes a plurality of laminated circuit board units with an insulating layer disposed between the adjacent circuit board units, the insulating layer is thinned to expose contact pads of circuit layers formed on the circuit board units, so as to allow the circuit board units to be laminated and electrically connected together by the exposed contact pads, the circuit board units having their laminated surfaces activated.

The multi-layer circuit board and the method for fabricating the same according to the invention have the combined advantages of laminating press and build-up processes. First, the plurality of circuit board units can be pre-formed with predetermined patterned circuits simultaneously and thus can be tested before subject to subsequent fabrication processes, thereby improving the fabrication yield and avoiding the prior-art problem of defective products from the build-up process. Moreover, the circuit board units undergo the surface activation process in vacuum by plasma, reactive ionic etching (RIE) or ion metal plasma (IMP) to form surfaces with nano-scale structure of atoms and molecules, so as to allow these circuit board units to be laminated in vacuum under the room temperature. This can eliminate the prior-art problems such as thermal stress and warpage due to CTE mismatch and requiring extra cost on conductive materials (e.g. tin paste, etc.) from the laminating press process. Furthermore, the fabrication method according to the invention allows two or more circuit board units to be laminated at one time for fabricating the multi-layer circuit board. This effectively shortens the fabrication time and reduces the fabrication cost and process complexity. Lastly, the circuit board units may have their insulating layers thinned in advance, making the multi-layer circuit board formed by these thinned circuit board units lighter in weight and smaller in thickness and suitable for use in small-scale electronic devices.

### BRIEF DESCRIPTION OF THE DRAWINGS

The present invention can be more fully understood by reading the following detailed description of the preferred embodiments, with reference made to the accompanying drawings, wherein:

FIGS. 1A to 1F (PRIOR ART) are cross-sectional views showing the procedural steps for fabricating a multi-layer circuit board by a conventional laminating press process;

FIGS. 2A to 2E (PRIOR ART) are cross-sectional views showing the procedural steps for fabricating a multi-layer circuit board by a conventional build-up process;

FIGS. 3A to 3E are cross-sectional views showing the procedural steps of a method for fabricating a multi-layer circuit board according to a preferred embodiment of the invention;

FIGS. 4A to 4C are cross-sectional views of a circuit board unit according to the invention;

FIGS. 5A and 5B are cross-sectional views showing the steps of connecting circuit board units together in the use of the method for fabricating a multi-layer circuit board according to the invention;

FIGS. 6A to 6E are cross-sectional views showing the procedural steps of a method for fabricating a multi-layer circuit board according to another preferred embodiment of the invention; and

FIGS. 7A and 7B are cross-sectional views showing the steps of connecting circuit board units together in the use of the method for fabricating a multi-layer circuit board according to the invention.

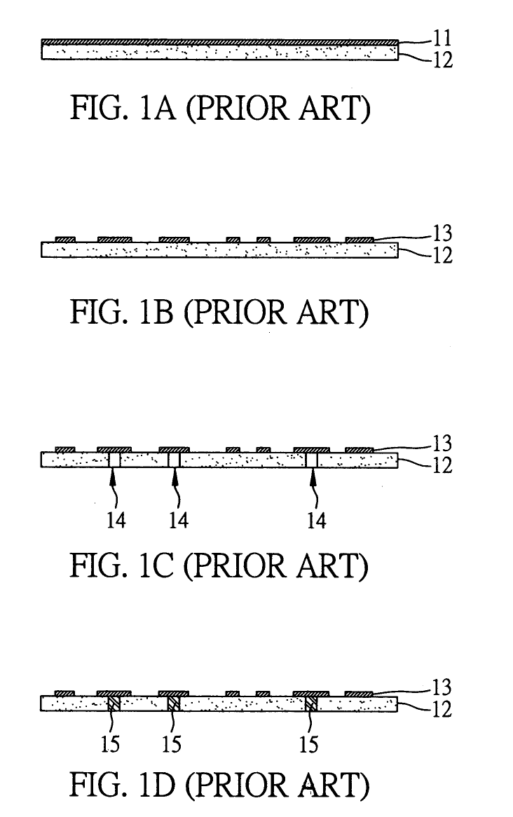

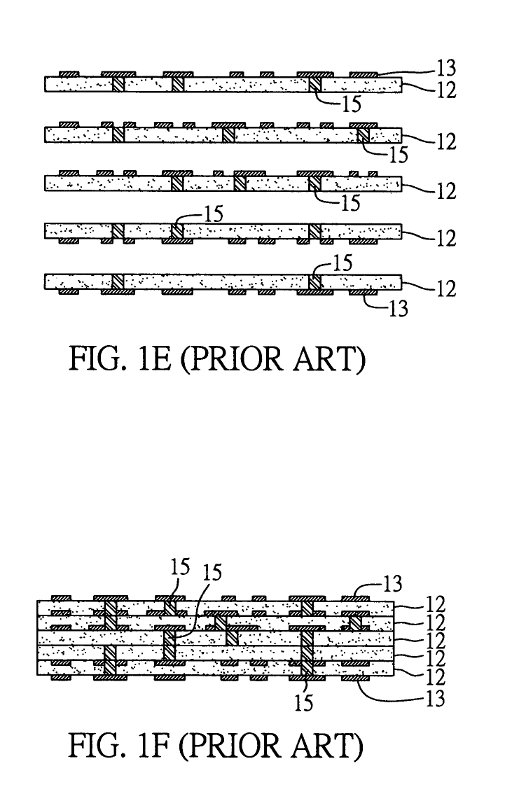

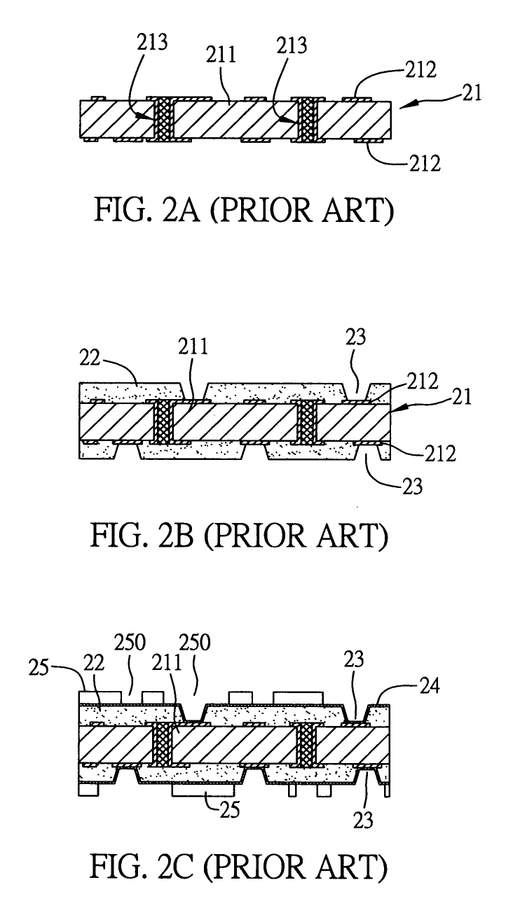

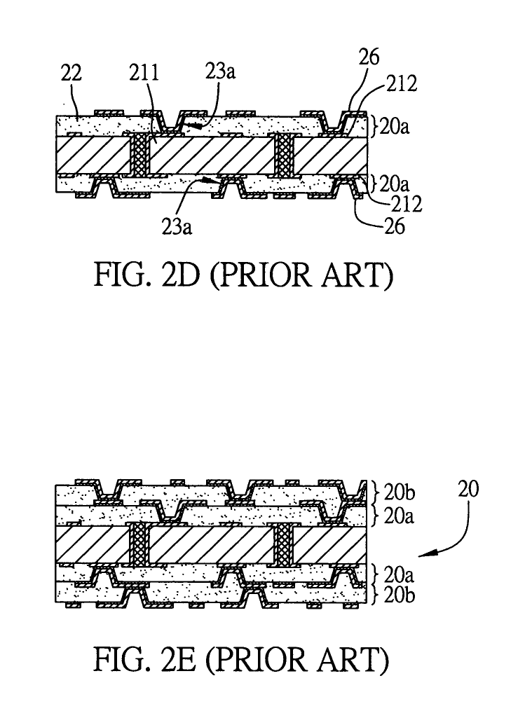

### DETAILED DESCRIPTION OF THE PREFERRED EMBODIMENTS

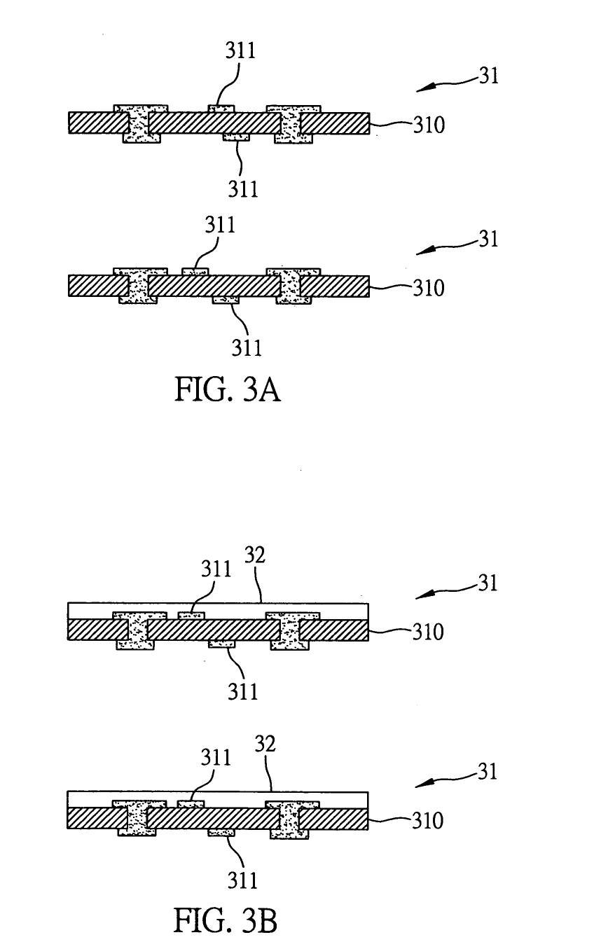

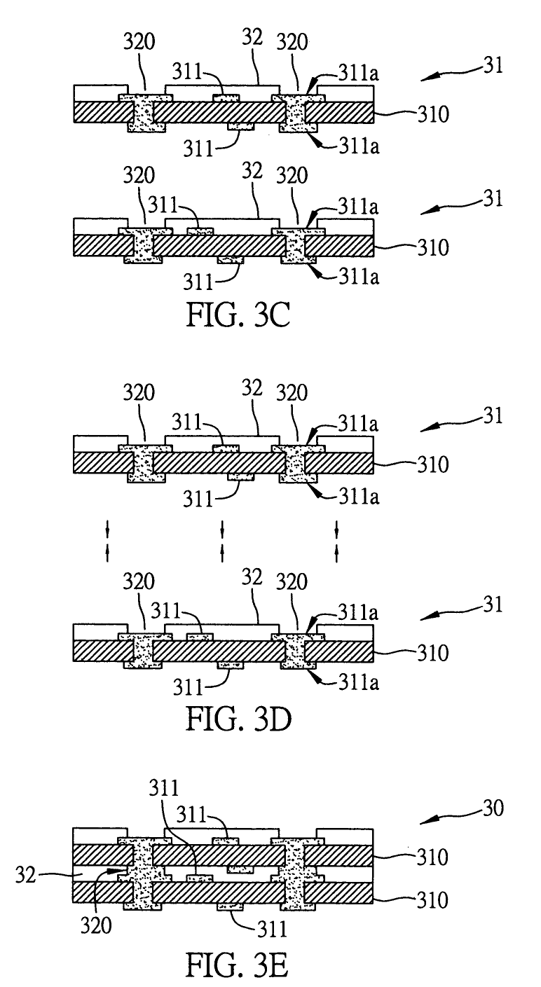

FIGS. 3A to 3E show the procedural steps of a method for fabricating a multi-layer circuit board according to a preferred embodiment of the present invention.

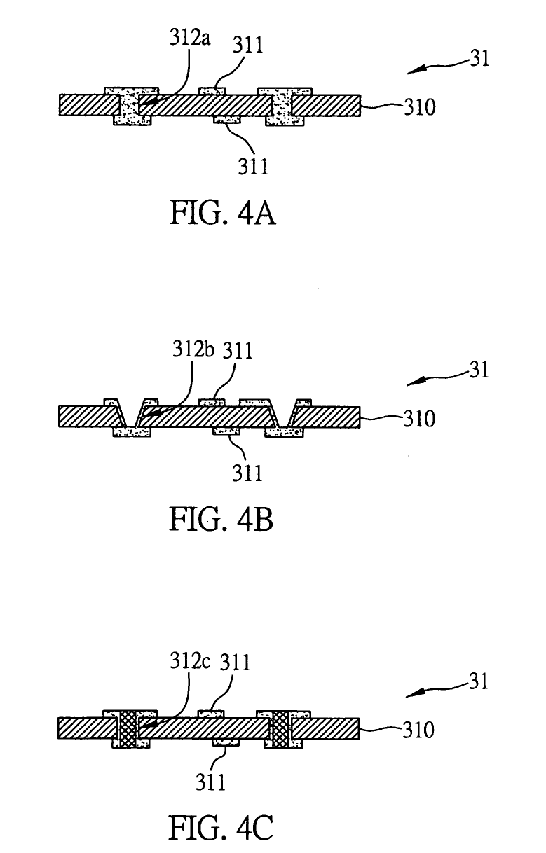

As shown in FIG. 3A, the first step is to prepare a plurality of circuit board units 31; each circuit board unit 31 can be a single-layer, double-layer or multi-layer structure. The circuit board unit 31 comprises a first insulating layer 310, patterned circuit layers 311 formed on the first insulating layer 310, and a plurality of conductive vias 312 for electrically interconnecting the circuit layers 311 as shown in FIG. 4A, wherein the conductive vias 312a are filled with a conductive material to mediate the electrical connection. Another example of the circuit board unit 31 is shown in FIG. 4B, wherein a plurality of conductive blind holes 312b are formed through the circuit board unit 31 but not penetrating the circuit layer 311 on one side (bottom side as shown) of the first insulating layer 310, and the conductive blind holes 312b may be or may not be filled with a conductive material. Alternatively, as shown in FIG. 4C, the circuit board unit 31 can have a plurality of plated through holes 312c, which are formed by plating a conductive metal layer on the inner walls of holes through the first insulating layer 310, and applying a conductive or non-conductive material for filling up the holes, so as to ensure the reliability of the plated through holes 312c. It should be understood that the structure of circuit board unit 31 is not limited to the above ones shown in FIGS. 4A to 4C. And fabrication of the circuit board unit 31 employs conventional technology, which is not to be further detailed here.

As shown in FIGS. 3B and 3C, a second insulating layer 32 is formed on at least one side of each of the circuit board units 31 and covers the corresponding circuit layer 311 on this side. The second insulating layer 32 is patterned to form a plurality of openings 320 for exposing contact pads 311a of the circuit layer 311. The second insulating layer 32 can be made of epoxy resin, polyimide, cyanate ester, glass fiber, bismaleimide triazine (BT), or a mixture of epoxy resin and glass fiber (FR5) etc. A flattening process such as polishing can be performed on surfaces of the circuit board units 31, and a cleaning process can be carried out to remove any oxidation layer and contamination on the surfaces of the circuit board units 31 in a suitable environment such as vacuum, inert gas or chemical solution, so as to ensure the quality of the surfaces of the circuit board units 31 for subsequent fabrication processes e.g. surface activation.

As shown in FIG. 3D, the circuit board units 31 are placed in vacuum and subject to the surface activation process by means of plasma, reactive ionic etching (RIE) or ion metal plasma (IMP), to allow the surfaces of the circuit board units 31 predetermined for lamination to have nano-scale structure of atoms and molecules. As a result, the laminating process can be performed under the room temperature in vacuum to vertically stack a pair of the circuit board units 31 together with the contact pads 311a of the overlying circuit board unit 31 electrically connected to the contact pads 311a exposed via the openings 320 of the underlying circuit board unit 31, such that a multi-layer circuit board 30 is fabricated as shown in FIG. 3E. The surface activation and laminating processes in vacuum can be repeated to stack a desirable number of circuit board units 31 to form the multi-layer circuit board 30.

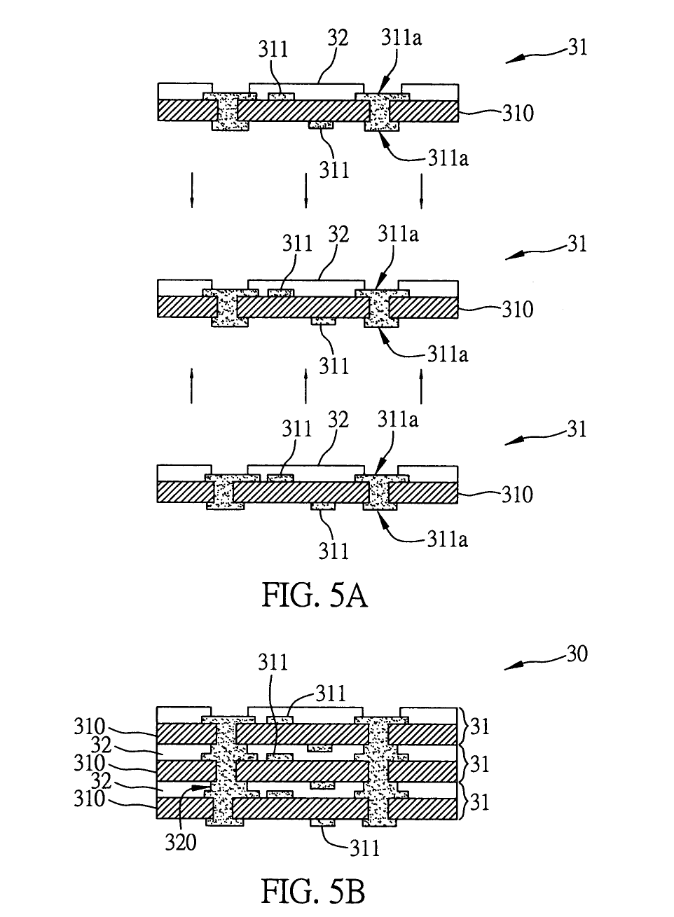

Moreover, as shown in FIGS. 5A and 5B, the laminating process allows three or more circuit board units 31 to be stacked together at one time during fabrication of the multi-layer circuit board 30. This shortens the fabrication time and makes the fabrication processes much simpler to implement. For increasing the bonding strength between adjacent circuit board units 31, the circuit board units 31 after lamination are baked to dissipate any remaining moisture.

Referring to FIG. 3E or 5B, the above fabricated multi-layer circuit board 30 comprises a plurality of circuit board units 31, with the second insulating layer 32 disposed between adjacent circuit board units 31. The openings 320 of the second insulating layer 32 expose the contact pads 311a of the underlying circuit board unit 31, such that these exposed contact pads 311a can be electrically connected to the contact pads 311a of the overlying circuit board unit 31 that are engaged with the openings 320, thereby making the stack of circuit board units 31 securely and electrically interconnected.

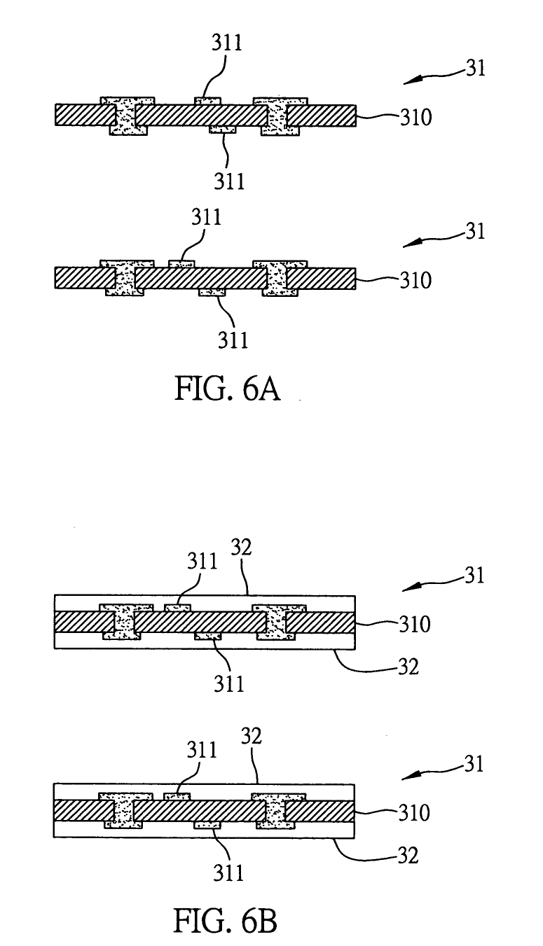

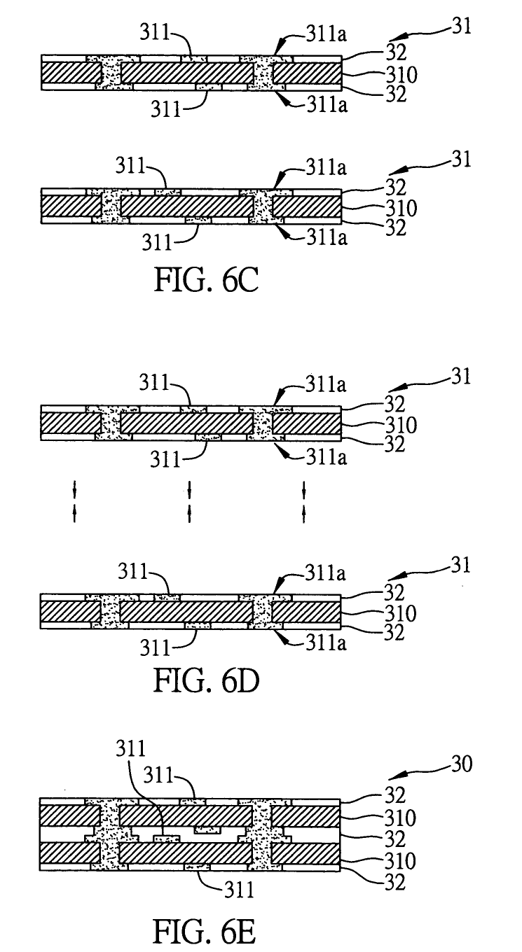

FIGS. 6A to 6E show the procedural steps of a method for fabricating a multi-layer circuit board according to another preferred embodiment of the invention.

As shown in FIG. 6A, similar to the step of FIG. 3A, first, a plurality of circuit board units 31 are prepared, each comprising a first insulating layer 310 and patterned circuit layers 311 on the first insulating layer 310 and having, but not limited to, the structure of FIG. 4A, 4B or 4C.

As shown on FIGS. 6B and 6C, a second insulating layer 32 is formed on top and bottom surfaces of each of the circuit board units 31 and covers the corresponding circuit layer 311. The second insulating layers 32 are thinned or partly removed by polishing to at least expose contact pads 311a of the circuit layers 311. The circuit board units 31 can undergo the above flattening and cleaning processes to be ready for the subsequent surface activation process.

As shown in FIG. 6D, the circuit board units 31 are placed in vacuum and subject to the surface activation process by means of plasma, RIE or IMP, to allow the surfaces of the circuit board units 31 predetermined for lamination to have nano-scale structure of atoms and molecules. As a result, the laminating process can be performed under the room temperature in vacuum to vertically stack a pair of the circuit board units 31 together with the contact pads 311a of the overlying circuit board unit 31 electrically connected to the contact pads 311a of the underlying circuit board unit 31, such that a multi-layer circuit board 30 is fabricated as shown in FIG. 6E. The surface activation and laminating processes in vacuum can be repeated to stack a desirable number of circuit board units 31 to form the multi-layer circuit board 30.

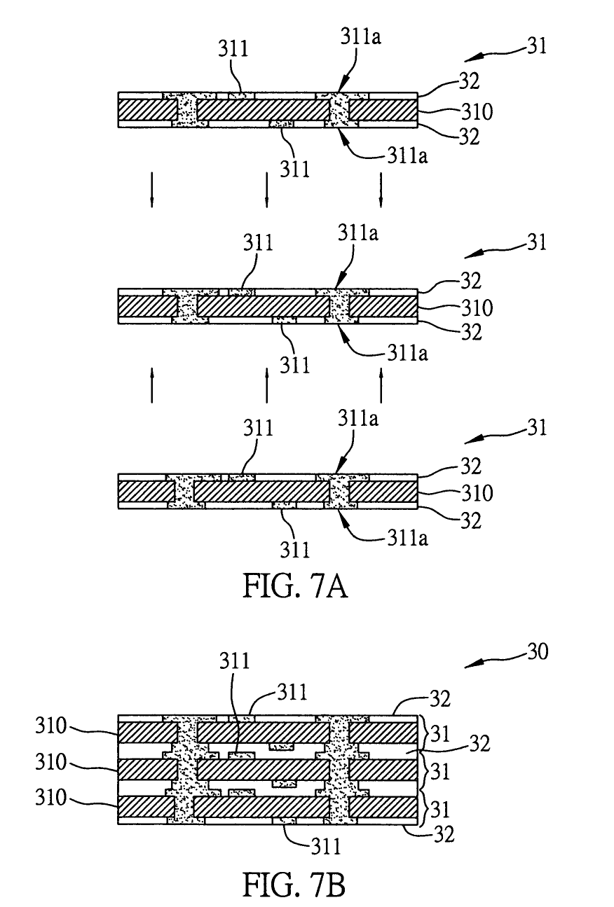

Moreover, as shown in FIGS. 7A and 7B, the laminating process allows three or more circuit board units 31 with thinned second insulating layers 32 to be stacked together at one time during fabrication of the multi-layer circuit board 30. This shortens the fabrication time and makes the fabrication processes much simpler to implement. For increasing the bonding strength between adjacent circuit board units 31, the circuit board units 31 after lamination are baked to dissipate any remaining moisture.

Referring to FIG. 6E or 7B, the above fabricated multi-layer circuit board 30 comprises a plurality of circuit board units 31, with the second insulating layers 32 disposed between adjacent circuit board units 31. The second insulating layers 32 are thinned to expose the contact pads 311a of the adjacent circuit board units 31 that can thus be securely and electrically interconnected by these exposed contact pads 311a.

The multi-layer circuit board and the method for fabricating the same according to the invention have the combined advantages of laminating press and build-up processes. First, the plurality of circuit board units can be pre-formed with predetermined patterned circuits simultaneously and thus can be tested before subject to subsequent fabrication processes, thereby improving the fabrication yield and avoiding the prior-art problem of defective products from the build-up process. Moreover, the circuit board units undergo the surface activation process in vacuum by plasma, RIE or IMP to form surfaces with nano-scale structure of atoms and molecules, so as to allow these circuit board units to be laminated in vacuum under the room temperature. This can eliminate the prior-art problems such as thermal stress and warpage due to CTE mismatch and requiring extra cost on conductive materials (e.g. tin paste, etc.) from the laminating press process. Furthermore, the fabrication method according to the invention allows two or more circuit board units to be laminated at one time for fabricating the multi-layer circuit board. This effectively shortens the fabrication time and reduces the fabrication cost and process complexity. Lastly, the circuit board units may have their insulating layers (second insulating layers) thinned in advance, making the multi-layer circuit board formed by these thinned circuit board units lighter in weight and smaller in thickness and suitable for use in small-scale electronic devices.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method for fabricating a multi-layer circuit board, comprising:
providing a plurality of circuit board units each of which is formed with patterned circuit layers;
forming at least one insulating layer on each of the circuit board units to cover at least one of the circuit layers, and exposing a predetermined part of the circuit layer from the insulating layer; and
placing the circuit board units in vacuum to perform a surface activation process and an laminating process.

2. The method of claim 1, wherein the insulating layer is patterned to form a plurality of openings for exposing the predetermined part of the circuit layer.

3. The method of claim 1, wherein the insulating layer is thinned to expose the predetermined part of the circuit layer.

4. The method of claim 3, wherein the insulating layer is partly removed by polishing to expose the predetermined part of the circuit layer.

5. The method of claim 1, wherein surfaces of the circuit board units are flattened before the surface activation process.

6. The method of claim 5, wherein the flattened circuit board units are cleaned to remove oxidation layers and contamination on the surfaces thereof.

7. The method of claim 1, wherein the laminating process for the circuit board units is performed in vacuum under the room temperature.

8. The method of claim 1, further comprising baking the circuit board units after lamination.

9. The method of claim 1, wherein the circuit board units each has a single-layer, double-layer or multi-layer structure.

10. The method of claim 1, wherein the laminating process allows the circuit board units to be laminated all at one time or in several times.

11. The method of claim 1, wherein the surface activation process is performed by subjecting the circuit board units to plasma, reactive ionic etching (RIE) or ion metal plasma (IMP), so as to form surfaces of the circuit board units with a nano-scale structure of atoms and molecules.

12. The method of claim 1, wherein the exposed predetermined part of the circuit layer comprises a plurality of contact pads, allowing the circuit board units to be laminated and electrically connected together by the contact pads.

13. A multi-layer circuit board comprising a plurality of laminated circuit board units with an insulating layer disposed between the adjacent circuit board units, the insulating layer having a plurality of openings for exposing contact pads of circuit layers formed on the circuit board units, so as to allow the circuit board units to be laminated and electrically connected together by the exposed contact pads, the circuit board units having their laminated surfaces activated.

14. The multi-layer circuit board of claim 13, wherein the circuit board units each has a single-layer, double-layer or multi-layer structure.

15. The multi-layer circuit board of claim 13, wherein the laminated surfaces of the circuit board units are activated by plasma, reactive ionic etching (RIE) or ion metal plasma (IMP) to have a nano-scale structure of atoms and molecules.

16. A multi-layer circuit board comprising a plurality of laminated circuit board units with an insulating layer disposed between the adjacent circuit board units, the insulating layer is thinned to expose contact pads of circuit layers formed on the circuit board units, so as to allow the circuit board units to be laminated and electrically connected together by the exposed contact pads, the circuit board units having their laminated surfaces activated.

17. The multi-layer circuit board of claim 16, wherein the circuit board units each has a single-layer, double-layer or multi-layer structure.

18. The multi-layer circuit board of claim 16, wherein the laminated surfaces of the circuit board units are activated by plasma, reactive ionic etching (RIE) or ion metal plasma (IMP) to have a nano-scale structure of atoms and molecules.
